(19) United States
(12) Patent Application Publication
(10) Pub. No.: US 2021/0119099 A1
(43) Pub. Date: Apr. 22, 2021

(54) THERMOELECTRIC MODULE AND METHOD FOR MANUFACTURING THERMOELECTRIC MODULE POST

(71) Applicant: KELK Ltd., Kanagawa (JP)

(72) Inventor: Hiroyuki MATSUNAMI, Kanagawa (JP)

(21) Appl. No.: 17/071,630

(22) Filed: Oct. 15, 2020

(30) Foreign Application Priority Data
Oct. 16, 2019 (JP) 2019189374
Oct. 16, 2019 (JP) 2019189375
Oct. 16, 2019 (JP) 2019189376

(51) Int. Cl. H01L 35/10; H01L 35/32; G02B 6/42; H01L 35/34; H01S 5/024; H04B 10/40; H01L 35/30; H01S 5/00

(52) U.S. Cl. CPC H01L 35/10; H01L 35/32; G02B 6/4204; H01L 35/34; H01S 5/0064; H01S 5/02415; H04B 10/40; H01L 35/30; H01S 5/02469

(57) ABSTRACT

Provided is a thermoelectric module capable of further suppressing electrochemical migration with a simple structure. A thermoelectric module includes: a lower substrate; an upper substrate disposed above the lower substrate so as to be opposite to the lower substrate; a plurality of p-type thermoelectric elements and n-type thermoelectric elements disposed between the lower substrate and the upper substrate; first electrodes disposed on an upper surface of the lower substrate and a lower surface of the upper substrate, and sequentially connecting the p-type and n-type thermoelectric elements alternately to form a series circuit; and a second electrode that is provided on the lower substrate and connects a thermoelectric element at an end of the series circuit to a post, in which the post includes a post body formed of nickel, and a nickel passivation film covering a side surface of the post body.

### CROSS-REFERENCE TO RELATED APPLICATIONS

This application is claims priority Japanese Patent Application No. 2019-189374, filed on Oct. 16, 2019, Japanese Patent Application No. 2019-189375, filed on Oct. 16, 2019, and Japanese Patent Application No. 2019-189376, filed on Oct. 16, 2019. The contents of the prior applications are incorporated herein in their entirety.

### TECHNICAL FIELD

The present invention relates to a thermoelectric module and a method for manufacturing a thermoelectric module post.

### BACKGROUND

A thermoelectric module has been widely used as a circuit element that absorbs or generates heat by the Peltier effect. As an example, as described in Japanese Unexamined Patent Application, First Publication No. 2016-111326, a thermoelectric module includes a p-type thermoelectric element, an n-type thermoelectric element, a pair of electrodes connecting the thermoelectric elements, and a post for supplying a current to the electrodes, and a housing that covers the thermoelectric elements, the electrodes, and the posts, from an outside.

The p-type thermoelectric elements and the n-type thermoelectric elements are connected alternately and in series, and columnar posts formed of nickel are provided at both ends of the series circuit, respectively. A current is supplied by using one post as a positive electrode and the other post as a negative electrode. Accordingly, the Peltier effect is developed in the thermoelectric element, heat is absorbed in one electrode, and heat is generated in the other electrode.

Here, in a case where a controlled temperature of the thermoelectric element is lower than a dew point of a surrounding environmental atmosphere, dew condensation may occur in the thermoelectric module. When the dew condensation occurs, a phenomenon called electrochemical migration is induced on a surface of the post. The electrochemical migration is a phenomenon in which insulation between electrodes on an electric circuit becomes defective due to electrical, chemical, and heat factors, and electrode metal is eluted and reduced as ions to cause a short circuit.

In order to avoid the electrochemical migration, it is conceivable to seal the housing against the outside and fill the housing with an inert gas.

Also, in order to avoid the phenomenon, for example, a device described Japanese Unexamined Patent Application, First Publication No. 2009-206501 adopts a configuration of providing, in addition to a circuit board of a thermoelectric module, a dummy board electrically independent of the circuit board.

It is described that, accordingly, a possibility that a short circuit will occur immediately in the circuit can be reduced when the electrochemical migration occurs. Also, it is described a technique of preventing water droplets from staying, by applying a water-repellent treatment to the dummy substrate and further reducing the frequency of short circuits.

### SUMMARY

In a case where the housing is hermetically sealed as described above and the housing is filled with the inert gas, manufacturing costs and the number of man-hours increase, which is not economical. Therefore, demand for a thermoelectric module that can further suppress electrochemical migration with a simple structure increases.

In addition, in a case where the dummy substrate is provided as described above, a primary short circuit can be avoided, but a secondary or tertiary short circuit cannot be avoided. In addition, a space for mounting the thermoelectric element may be reduced.

The present invention has been made to solve the problems, and an object thereof is to provide a thermoelectric module capable of further suppressing electrochemical migration with a simple configuration, and a method for manufacturing a thermoelectric module post.

According to a first aspect of the present invention, a thermoelectric module includes: a lower substrate; an upper substrate disposed above the lower substrate so as to be opposite to the lower substrate; a plurality of p-type thermoelectric elements and n-type thermoelectric elements disposed between the lower substrate and the upper substrate; first electrodes disposed on an upper surface of the lower substrate and a lower surface of the upper substrate, and sequentially connecting the p-type and n-type thermoelectric elements alternately to form a series circuit; and a second electrode that is provided on the lower substrate and connects a thermoelectric element at an end of the series circuit to a post, in which the post includes a post body formed of nickel, and a nickel passivation film covering a side surface of the post body.

According to a second aspect of the present invention, a thermoelectric module includes: a lower substrate; an upper substrate disposed above the lower substrate so as to be opposite to the lower substrate; a plurality of p-type thermoelectric elements and n-type thermoelectric elements disposed between the lower substrate and the upper substrate; electrodes disposed on an upper surface of the lower substrate and a lower surface of the upper substrate, and sequentially connecting the p-type thermoelectric elements and the n-type thermoelectric elements alternately so as to form a series circuit; a pair of posts that are erected on the lower substrate at an interval and are electrically connected to both ends of the series circuit, respectively; and a water-repellent coating layer laminated on a region between the pair of posts on the lower substrate.

According to a third aspect of the present invention, a thermoelectric module includes: a lower substrate; an upper substrate disposed above the lower substrate so as to be opposite to the lower substrate; a plurality of p-type thermoelectric elements and n-type thermoelectric elements disposed between the lower substrate and the upper substrate; connection electrodes disposed on an upper surface of the lower substrate and a lower surface of the upper substrate, and sequentially connecting the p-type thermoelectric elements and the n-type thermoelectric elements alternately so as to form a series circuit; an end electrode that is disposed on the upper surface of the lower substrate and is connected to the thermoelectric element at an end of the series circuit; a heating thermoelectric element that is disposed on the end electrode and has the same majority carrier as the thermoelectric element at the end of the series circuit; and a post erected on the heating thermoelectric element.

According to the present invention, it is possible to provide a thermoelectric module capable of further suppressing electrochemical migration with a simple configuration, and a method for manufacturing a thermoelectric module post.

### BRIEF DESCRIPTION OF THE DRAWINGS

FIG. 1 is a sectional view showing a configuration of an optical module according to first to third embodiments of the present invention.

FIG. 2 is a sectional view showing a configuration of a thermoelectric module according to the first embodiment of the present invention.

FIG. 3 is a perspective view showing a configuration of a post according to the first embodiment of the present invention.

FIG. 4 is a flowchart showing each step of a method for manufacturing a post according to the first embodiment of the present invention.

FIG. 5 is a perspective view showing a configuration of an element body in a preparation step, in the method for manufacturing a post according to the first embodiment of the present invention.

FIG. 6 is a perspective view showing a configuration of a plated element body after a plating step is completed in the method for manufacturing a post according to the first embodiment of the present invention.

FIG. 7 is a perspective view showing a state after a dicing step is completed in the method for manufacturing a post according to the first embodiment of the present invention.

FIG. 8 is a sectional view showing a configuration of a thermoelectric module according to the second embodiment of the present invention.

FIG. 9 is a plan view showing a configuration of the thermoelectric module according to the second embodiment of the present invention.

FIG. 10 is an enlarged plan view of a main part of the thermoelectric module according to the second embodiment of the present invention.

FIG. 11 is an enlarged side view of a main part of the thermoelectric module according to the second embodiment of the present invention.

FIG. 12 is a plan view of the thermoelectric module according to the third embodiment of the present invention.

FIG. 13 is a sectional view taken along line in FIG. 12.

FIG. 14 is a sectional view taken along line IV-IV in FIG. 12.

### DETAILED DESCRIPTION

(Configuration of Optical Module)

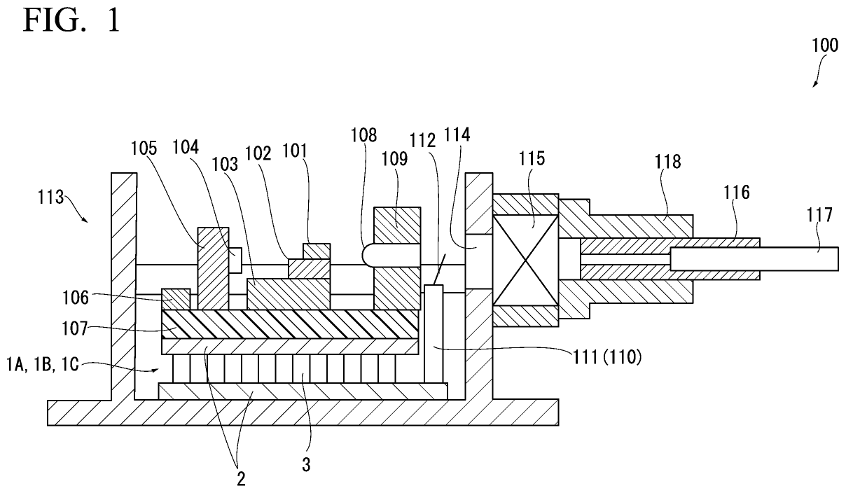

Hereinafter, an optical module 100 and a thermoelectric modules 1A to 1C according to an embodiment of the present invention will be described with reference to FIGS. 1 to 14. The optical module 100 is used for optical communication, for example.

As shown in FIG. 1, the optical module 100 includes thermoelectric modules 1A to 1C, a light emitting element 101, a heat sink 102, a first header 103, a light receiving element 104, a second header 105, a temperature sensor 106, a metal plate 107, a lens 108, a lens holder 109, a wire 112, and a housing 113.

Further, the optical module 100 includes an optical isolator 115, an optical ferrule 116, an optical fiber 117, and a sleeve 118.

The thermoelectric modules 1A to 1C are circuit elements that absorb or generate heat by the Peltier effect. Detailed configurations of the thermoelectric modules 1A to 1C will be described later.

The light emitting element 101 emits light. The light emitting element 101 includes, for example, a laser diode that emits laser light. The heat sink 102 supports the light emitting element 101. The heat sink 102 dissipates the heat generated by the light emitting element 101. The first header 103 supports the heat sink 102. The heat sink 102 is fixed to the first header 103.

The light receiving element 104 detects the light generated from the light emitting element 101. The light receiving element 104 includes, for example, a photodiode. The second header 105 supports the light receiving element 104. The light receiving element 104 is fixed to the second header 105.

The temperature sensor 106 detects a temperature of the metal plate 107. The temperature sensor 106 includes, for example, a thermistor.

The metal plate 107 supports the first header 103, the second header 105, and the temperature sensor 106. The first header 103, the second header 105, and the temperature sensor 106 are fixed to the metal plate 107 by soldering.

The lens 108 collects the light emitted from the light emitting element 101. The lens holder 109 supports the lens 108.

The housing 113 houses the thermoelectric modules 1A to 1C, the light emitting element 101, the heat sink 102, the first header 103, the light receiving element 104, the second header 105, the temperature sensor 106, the metal plate 107, the lens 108, and the lens holder 109. The housing 113 is formed with an aperture 114 through which the light emitted from the light emitting element 101 passes.

The optical isolator 115 is disposed on an outside of the housing 113 so as to close the aperture 114. The optical isolator 115 allows light traveling in one direction to pass through and blocks light traveling in a backward direction. The light emitted from the light emitting element 101 and passing through the lens 108 enters the optical isolator 115 via the aperture 114. The light that has entered the optical isolator 115 passes through the optical isolator 115.

The optical ferrule 116 guides the light emitted from the optical isolator 115 to the optical fiber 117. The sleeve 118 supports the optical ferrule 116.

Next, an operation of the optical module 100 will be described. The light emitted from the light emitting element 101 is collected by the lens 108 and then enters the optical isolator 115 via the aperture 114. The light that has entered the optical isolator 115 passes through the optical isolator 115 and then enters the end surface of the optical fiber 117 through the optical ferrule 116.

The heat generated from the light emitting element 101 is transferred to the metal plate 107 via the heat sink 102 and the first header 103. The temperature sensor 106 detects the temperature of the metal plate 107. When the temperature sensor 106 detects that the temperature of the metal plate 107 has reached a predetermined specified temperature, a current is supplied from the thermoelectric module 1A to the thermoelectric module 1C. When the thermoelectric elements 3 of the thermoelectric modules 1A to 1C are energized, the thermoelectric modules 1A to 1C absorb heat due to the Peltier effect. As a result, the light emitting element 101 is cooled. The temperature of the light emitting element 101 is controlled by the thermoelectric module.

### First embodiment

### <Thermoelectric Module>

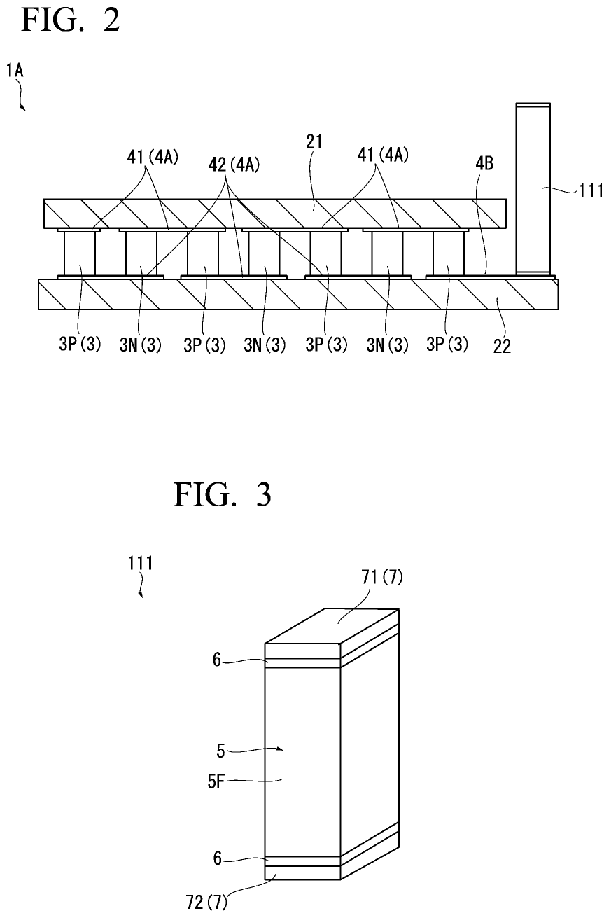

As shown in FIG. 2, the thermoelectric module 1A includes a pair of substrates 2 (an upper substrate 21 and a lower substrate 22), a plurality of thermoelectric elements 3 (a p-type thermoelectric element 3P and an n-type thermoelectric element 3N) which are disposed between the substrates 2, a first electrode 4A (an upper electrode 41 and a lower electrode 42) connecting the thermoelectric elements 3, a post 111, and a second electrode 4B.

The upper substrate 21 and the lower substrate 22 are formed of an electrically insulating material and have a plate shape. For example, the upper substrate 21 and the lower substrate 22 are formed of ceramic. The upper substrate 21 is disposed above the lower substrate 22 so as to be opposite to the lower substrate 22 and is disposed at an interval.

A plurality of thermoelectric elements 3 are disposed between the upper substrate 21 and the lower substrate 22 at intervals in a plane direction orthogonal to the thickness direction of the upper substrate 21 and the lower substrate 22. That is, the thermoelectric element 3 is disposed on the upper surface of the lower substrate 22 and the lower surface of the upper substrate 21 via the electrodes 4 to be described later, so as to be opposite to each other. The thermoelectric element 3 includes the p-type thermoelectric element 3P and the n-type thermoelectric element 3N, depending on polarities of a semiconductor included in the thermoelectric element 3. In the present embodiment, the p-type thermoelectric element 3P and the n-type thermoelectric elements 3N are arranged so as to alternate in cross-section.

As shown in FIG. 2, the upper electrodes 41 are provided on an upper end surfaces of the p-type thermoelectric element 3P and the n-type thermoelectric element 3N, and the lower electrodes 42 are provided on the lower end surfaces of the p-type thermoelectric element 3P and the n-type thermoelectric element 3N. Both the upper electrodes 41 and the lower electrodes 42 are wiring members formed of metal foil or the like on the substrate 2. The p-type thermoelectric element 3P and the n-type thermoelectric element 3N adjacent to the p-type thermoelectric element 3P are connected to each other by the lower electrode 42. The n-type thermoelectric element 3N and the p-type thermoelectric element 3P adjacent to the n-type thermoelectric element 3N are connected to each other by the upper electrode 41. Accordingly, the p-type thermoelectric elements 3P and the n-type thermoelectric elements 3N are alternately and sequentially connected to form a series circuit.

A post 111 is erected on the upper surface of the lower substrate 22. The post 111 is electrically connected to the thermoelectric element 3 located at the end of the series circuit described above via the second electrode 4B provided on the upper surface of the lower substrate 22. A wire 112 for supplying a current from the outside is connected to the upper end surface of the post 111. That is, a current is supplied from the wire 112 to the thermoelectric element 3 via the post 111. Although only one post 111 is shown in FIG. 2, two posts 111 are provided, one each for the positive electrode and the negative electrode.

### <Post>

As shown in FIG. 3, the post 111 includes a post body 5, an intermediate layer 6 provided on both end surfaces of the post body 5 in a vertical direction, a plating part 7 provided outside the intermediate layer 6, and a passivation film 5F (nickel passivation film) that covers a side surface of the post body 5.

The post body 5 has a prismatic shape integrally formed of nickel. The passivation film 5F is an oxide film formed on a nickel surface. The passivation film 5F does not dissolve away even when exposed to a solution or an acid, and thus protects the nickel inside (the post body 5) and suppresses progress of oxidation. The “side surface” of the post body 5 refers to four surfaces excluding a surface bonded to the lower electrode 42 and a surface opposite to the bonded surface.

The intermediate layer 6 is a metal film provided to improve biting of the plating part 7. Specifically, at least one kind selected from the group including gold, palladium, platinum, and rhodium is preferably used as the intermediate layer 6. It is also possible to adopt a configuration in which the plating part 7 (described later) is directly provided on the post body 5 without providing the intermediate layer 6.

The plating part 7 includes an upper plating part 71 (first plating part) formed on a first surface which is a surface of the post body 5 on an upper end side and a lower plating part 72 (second plating part) formed on a second surface which is a surface of the post body 5 on a lower end side. The upper plating part 71 is a plating layer formed of gold. The lower plating part 72 is a plating layer formed of an alloy of gold and tin. The intermediate layer 6 may be provided at least between the lower plating part 72 and the post 111 or between the upper plating part 71 and the post 111.

### <Manufacturing Method for Post>

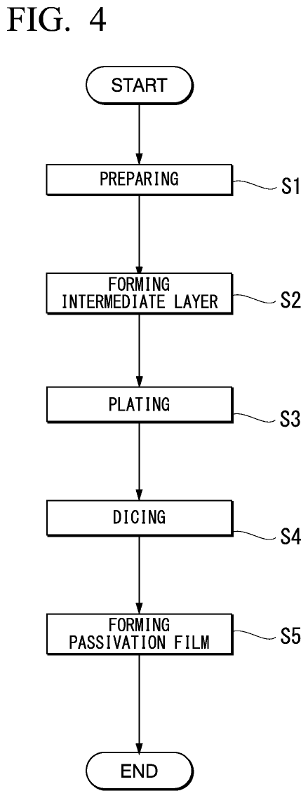

Next, a method for manufacturing the post 111 will be described with reference to FIGS. 4 to 6. As shown in FIG. 4, the manufacturing method includes a preparation step 51, an intermediate layer forming step S2, a plating step S3, a dicing step S4, and a passivation film forming step S5.

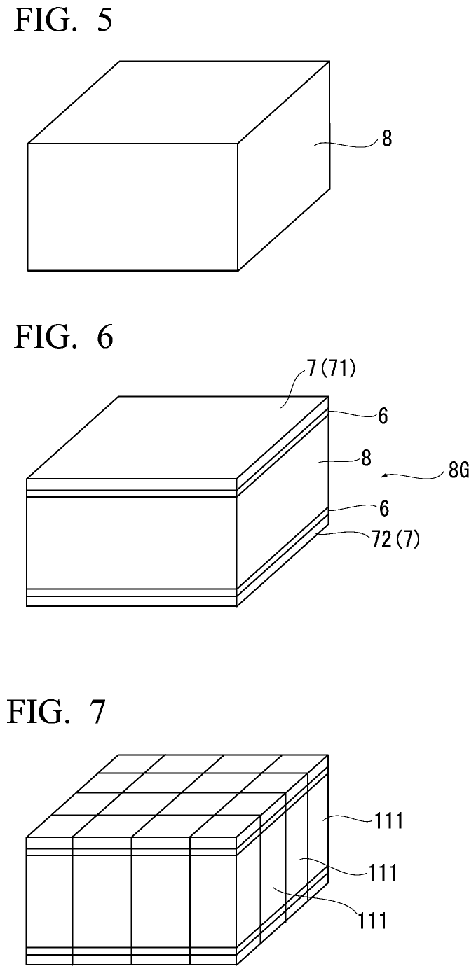

In the preparation step S1, a plate material (element body 8) formed of nickel is prepared (FIG. 5). The element body 8 has a pair of end surfaces which face directions away from each other in a thickness direction. More specifically, when the element body 8 spreads in an XY plane, the thickness direction is the Z-axis direction in an XYZ coordinate system. In the intermediate layer forming step S2, the intermediate layer 6 described above is formed on one surface (upper surface) and the other surface (lower surface) of the element body 8 in the thickness direction. It is also possible to perform the subsequent plating step S3 without performing the intermediate layer forming step S2. In the plating step S3, the plating part 7 described above is formed further outside the intermediate layer 6. Specifically, an upper plating part 71 formed of gold is formed on an upper surface side, and a lower plating part 72 formed of the alloy of gold and tin is formed on a lower surface side. As a result, a plated element body 8G is obtained (FIG. 6). Then, a dicing process is performed on the plated element body 8G (dicing step S4). The plated element body 8G is cut (diced) from the thickness direction in a grid pattern, by the dicing process. As a result, a plurality of posts 111 are obtained (FIG. 7). Then, the post 111 is immersed in an acidic solution (passivation film forming step S5). Concentrated nitric acid or hot concentrated sulfuric acid is preferably used as such a solution (oxidizing agent). Since the hot concentrated sulfuric acid is non-volatile, some components easily remain on the post 111 after manufacturing. Since the residual sulfuric acid component may cause an electrolytic reaction and the electrochemical migration occurs, it is more preferable to use the concentrated nitric acid. An oxidation reaction occurs on the side surface of the post 111, when contacting the solution. As a result, the passivation film 5F which is an oxide film is formed on the side surface of the post 111. Since the plating parts 7 formed of gold or gold and tin are formed on the upper end and the lower end of the post 111, the oxidation reaction by the solution does not occur. That is, in this step, the passivation film 5F is selectively formed only on the side surface of the post 111. As above, all the steps relating to the manufacturing of the post 111 are completed.

### <Effect>

Here, when a temperature controlled by the thermoelectric element 3 is lower than a dew point of a surrounding environmental atmosphere, dew condensation may occur in the thermoelectric module 1A. When the dew condensation occurs, a phenomenon called electrochemical migration is induced on the post 111. The electrochemical migration is a phenomenon in which insulation between electrodes on an electric circuit becomes defective due to electrical, chemical, and heat factors, and electrode metal is eluted and reduced as ions to cause a short circuit. When such a phenomenon occurs, a stable operation of the thermoelectric module 1A may be hindered. In order to avoid the electrochemical migration, a configuration to seal the housing against the outside and to fill the housing with an inert gas is conceivable as an example.

However, in a case where the housing is hermetically sealed and the housing is filled with the inert gas, manufacturing costs and the number of man-hours increase, which is not economical. Therefore, a demand for a thermoelectric module that can further suppress the electrochemical migration with a simple structure has increased.

Therefore, in the present embodiment, the post 111 (post body 5) is formed of nickel, and the passivation film 5F is formed on the side surface thereof. The passivation film 5F is formed, whereby it is possible to prevent denaturation or deterioration due to moisture content even when the dew condensation as above occurs. Accordingly, it is possible to increase environmental resistance of the post 111.

Also, in the above configuration, the upper plating part 71 formed of gold is formed on the upper end surface of the post body 5, and the lower plating part 72 formed of the alloy of gold and tin is formed on the lower end surface. Accordingly, it is possible to improve the bite when connecting (bonding) the wire 112 to the upper plating part 71. Also, it is possible to improve the biting of the lower plating part 72 to the lower electrode 42 due to soldering.

Further, the intermediate layer 6 is provided between the upper plating part 71 or the lower plating part 72 and the post body 5. As a result, it is possible to further reduce the possibility that the upper plating part 71 and the lower plating part 72 will be peeled or dropped off.

Further, according to the manufacturing method, the intermediate layer 6 and the plating part 7 are formed on both surfaces of the element body 8 in the thickness direction and then the plated element body 8G is only diced, whereby a large amount of posts 111 can be efficiently manufactured in a short time. Accordingly, it is possible to reduce man-hours and costs. Further, in the manufacturing method, the passivation film 5F can be easily formed selectively only on the side surface of the post 111, only by immersing the post 111 in the acidic solution. Also, in this case, since the upper end and the lower end of the post 111 are respectively covered with the plating part 7 containing gold, the oxidation reaction due to the solution does not occur. Accordingly, compared with a case where before forming the plating part 7 on the post body 5, the post body is immersed in a solution, and then passivation films at the upper end and lower end are removed to form the plating part 7, it is possible to make the manufacturing step more efficient by omitting the removing step.

### Second Embodiment

### <Thermoelectric Module>

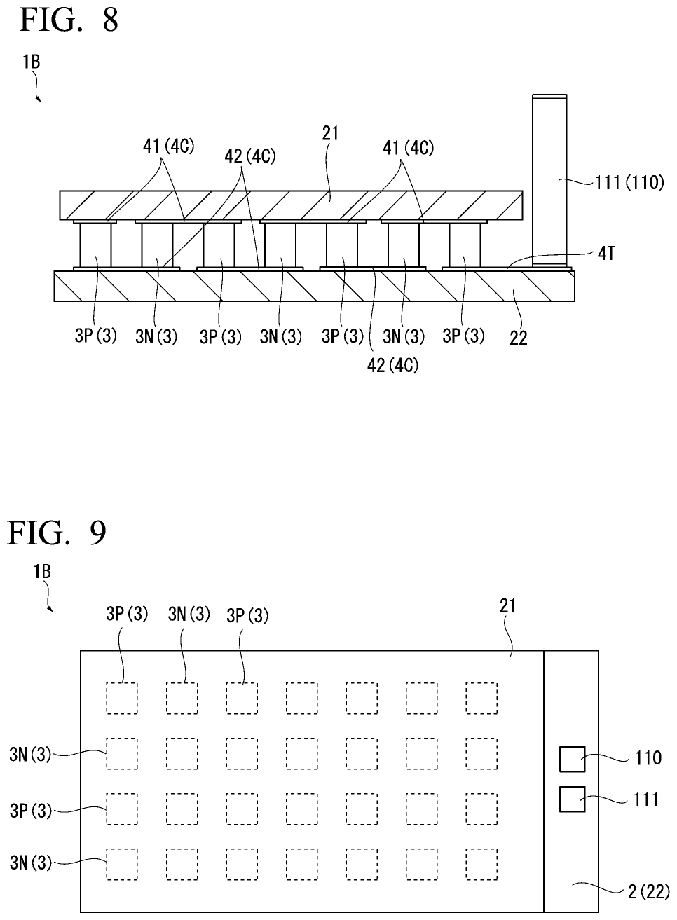

As shown in FIG. 8 or 9, the thermoelectric module 1B includes a pair of substrates 2 (an upper substrate 21 and a lower substrate 22), a plurality of thermoelectric elements 3 (a p-type thermoelectric element 3P and an n-type thermoelectric element 3N) which are disposed between the substrates 2, a connection electrode 4C (electrodes 4) connecting the thermoelectric elements 3, posts 110 and 111, and end electrode 4T connecting the posts 110 and 111 to the thermoelectric element 3.

The upper substrate 21 and the lower substrate 22 are formed of an electrically insulating material and have a plate shape. The upper substrate 21 is disposed above the lower substrate 22 so as to be opposite to the lower substrate 22, and is disposed at an interval. The upper substrate 21 and the lower substrate 22 are formed of ceramic, for example.

Each of the upper substrate 21 and the lower substrate 22 is a powder sintered body formed into a plate shape by sintering a ceramic powder and being impregnated with a permeable water-repellent material. In the present embodiment, both the upper substrate 21 and the lower substrate 22 include the permeable water-repellent material. Therefore, in a case where a water droplet adheres to the upper substrate 21 and the lower substrate 22, the water droplet is repelled by the water-repellent material component and move to another region.

A plurality of thermoelectric elements 3 are disposed between the upper substrate 21 and the lower substrate 22 at intervals in a plane direction orthogonal to the thickness direction of the upper substrate 21 and the lower substrate 22. That is, the thermoelectric element 3 is disposed so as to be opposite to the upper surface of the lower substrate 22 and the lower surface of the upper substrate 21 via the connection electrode 4C to be described later. The thermoelectric element 3 includes the p-type thermoelectric element 3P and the n-type thermoelectric element 3N, depending on polarities of a semiconductor included in the thermoelectric element 3. In the present embodiment, the p-type thermoelectric element 3P and the n-type thermoelectric elements 3N are arranged so as to alternate in cross-section.

The connection electrode 4C includes an upper electrode 41 and a lower electrode 42. As shown in FIG. 8, the upper electrodes 41 are provided on an upper end surfaces of the p-type thermoelectric element 3P and the n-type thermoelectric element 3N, and the lower electrodes 42 are provided on the lower end surfaces of the p-type thermoelectric element 3P and the n-type thermoelectric element 3N. Both the upper electrodes 41 and the lower electrodes 42 are wiring members formed of metal foil or the like on the substrate 2. The p-type thermoelectric element 3P and the n-type thermoelectric element 3N adjacent to the p-type thermoelectric element 3P are connected to each other by the lower electrode 42. The n-type thermoelectric element 3N and the p-type thermoelectric element 3P adjacent to the n-type thermoelectric element 3N are connected to each other by the upper electrode 41. Accordingly, the p-type thermoelectric elements 3P and the n-type thermoelectric elements 3N are alternately and sequentially connected to form a series circuit.

As shown in FIG. 9, a pair of posts 110 and 111 are erected on the upper surface of the lower substrate 22 at an interval. The posts 110 and 111 are electrically connected to the thermoelectric elements 3 positioned at the ends of the series circuit described above via the end electrodes 4T. The wires 112 for supplying a current from the outside are connected to the upper end surfaces of the posts 110 and 111. That is, the current is supplied from the wire 112 to the thermoelectric element 3 via the posts 110 and 111. The posts 110 and 111 each function as a positive electrode or a negative electrode.

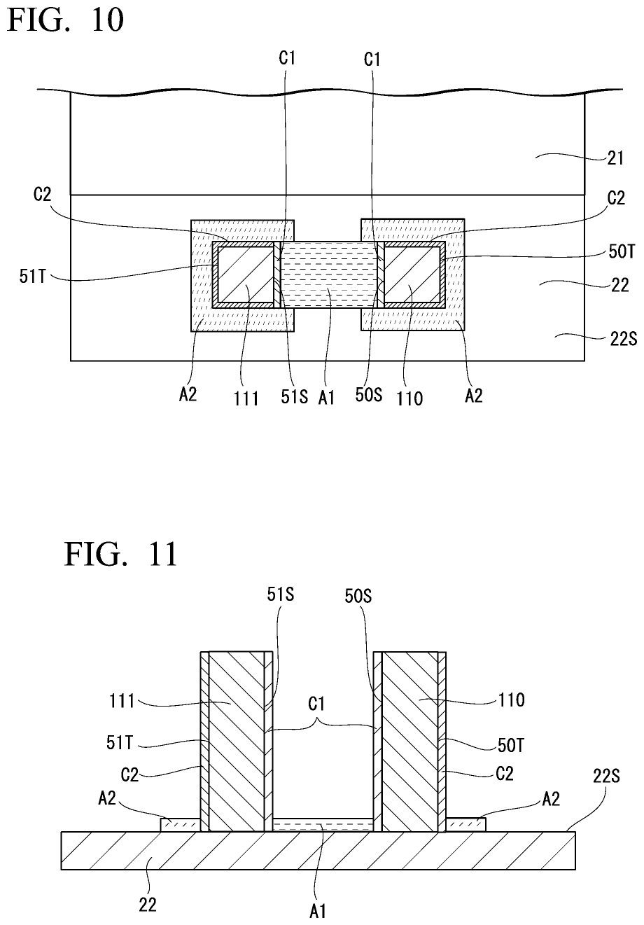

As shown in an enlarged view in FIG. 10 or 11, a water-repellent coating layer A1 laminated on an upper surface 22S of the lower substrate 22 is provided on a region between the posts 110 and 111. The water-repellent coating layer A1 is, for example, a thin film layer formed of a resin, and has a property of repelling water adhering thereto. Therefore, when a water droplet is formed on the water-repellent coating layer A1 due to the dew condensation, the water droplet is repelled by the water-repellent coating layer A1 and moves to another region.

Further, a hydrophilic coating layer A2 is provided on a region that surrounds the outer periphery of each of the posts 110 and 111 on the upper surface 22S of the lower substrate 22 in a ring shape, except for the region where the water-repellent coating layer A1 is provided. The hydrophilic coating layer A2 is a thin film layer formed of a different kind of resin from that of the water-repellent coating layer A1, and has a property of retaining water adhering thereto without repelling.

Further, on the surfaces (opposite surfaces SOS and 51S) of the posts 110 and 111 that are opposite to each other, opposite surface water-repellent coating layers C1 formed of a water-repellent material are provided. The opposite surface water-repellent coating layer C1 has a property of repelling water adhering thereto, like the water-repellent coating layer A1 described above. Therefore, when a water droplet is formed on the opposite surface water-repellent coating layer C1 due to the dew condensation, the water droplet is repelled by the opposite surface water-repellent coating layer C1 and then moves downward according to gravity.

In addition, in the posts 110 and 111, opposite surface hydrophilic coating layers C2 are provided respectively on outer surfaces 50T and 51T which are different from the opposite surfaces 50S and 51S. Here, the outer surface 50T is the remaining three surfaces excluding the opposite surface 50S when the post 110 is viewed in a plan view. The outer surface 51T is the remaining three surfaces excluding the opposite surface 51S when the post 111 is viewed in a plan view. The hydrophilic coating layer C2 has a property of retaining water adhering thereto without repelling, like the hydrophilic coating layer A2 described above.

### <Effect>

Here, when a temperature controlled by the thermoelectric element 3 is lower than a dew point of a surrounding environmental atmosphere, dew condensation may occur in the thermoelectric module 1B. When the dew condensation occurs, a phenomenon called electrochemical migration is induced on the posts 110 and 111. The electrochemical migration is a phenomenon in which insulation between electrodes on an electric circuit becomes defective due to electrical, chemical, and heat factors, and electrode metal is eluted and reduced as ions to cause a short circuit. When such a phenomenon occurs, a stable operation of the thermoelectric module 1B may be hindered.

Therefore, in the present embodiment, the water-repellent coating layer A1 is provided in a region between the posts 110 and 111 on the upper surface 22S of the lower substrate 22. As a result, when a water droplet is formed between the posts 110 and 111, the water droplet is repelled immediately when adhering to the water-repellent coating layer A1 and moves to another region. That is, it is possible to prevent the water droplet from staying between the posts 110 and 111. As a result, it is possible to reduce the possibility that the electrochemical migration described above will occur.

Further, in the present embodiment, the hydrophilic coating layer A2 is provided on a region surrounding the outer periphery of the posts 110 and 111 on the upper surface 22S of the lower substrate 22. Therefore, the water droplet repelled by the water-repellent coating layer A1 is captured by the hydrophilic coating layer A2. Accordingly, it is possible to reduce the possibility that the water droplet will flow out to another region.

As a result, it is possible to further reduce the possibility that the electrochemical migration described above will occur.

In addition, in the present embodiment, the opposite surface water-repellent coating layers C1 are provided on the opposite surfaces 50S and 51S of the posts 110 and 111, respectively. Therefore, the water droplet adhering to the opposite surface water-repellent coating layer C1 is repelled and then moves downward according to gravity. That is, it is possible to prevent the water droplet from staying on the opposite surface water-repellent coating layer C1. As a result, it is possible to reduce the possibility that the electrochemical migration described above will occur.

Further, in the present embodiment, the hydrophilic coating layer C2 is provided on the remaining outer surfaces 50T and 51T of the posts 110 and 111 excluding the opposite surfaces 50S and 51S. Therefore, among the water droplets repelled by the opposite surface water-repellent coating layer C1, some components that have not moved downward move toward the hydrophilic coating layer A2 side and are captured. Accordingly, it is possible to reduce the possibility that the water droplet will flow out to another region. As a result, it is possible to further reduce the possibility that the electrochemical migration described above will occur.

Also, in the present embodiment, at least one of the upper substrate 21 and the lower substrate 22 is formed by sintering ceramic powder and impregnating with a permeable water-repellent material.

Therefore, when a water droplet adheres to at least one of the upper substrate 21 and the lower substrate 22, the water droplet is repelled by the water-repellent material component and moves to another region. As a result, it is possible to further reduce the possibility that the electrochemical migration described above will occur.

### Third Embodiment

### <Thermoelectric Module>

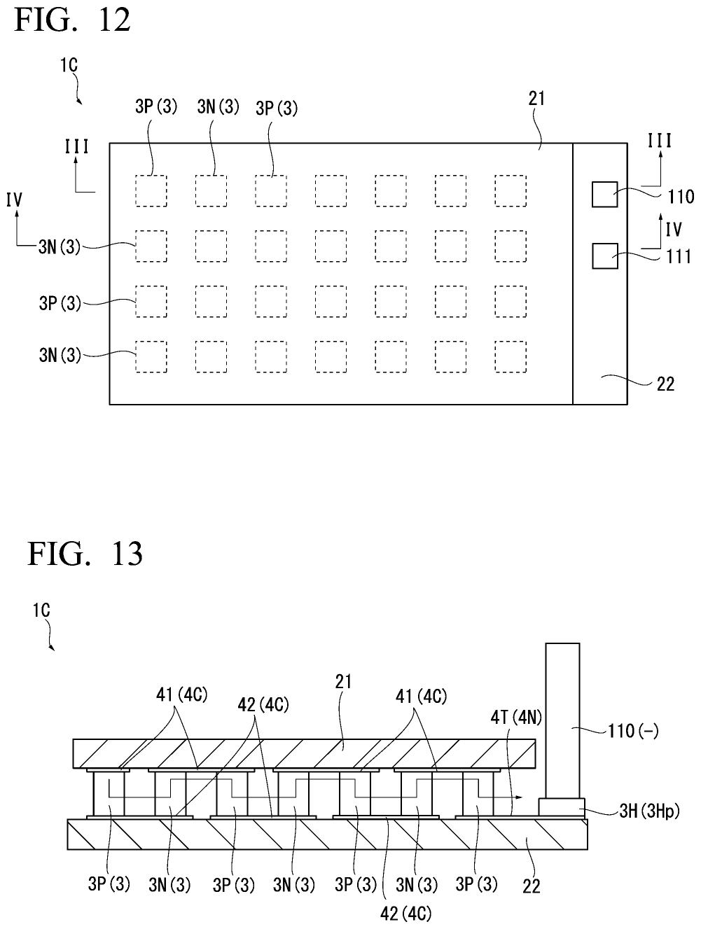

As shown in FIG. 12 or FIG. 13, the thermoelectric module 1C includes a pair of substrates 2 (an upper substrate 21 and a lower substrate 22) and a plurality of thermoelectric elements 3 (a p-type thermoelectric elements 3P and an n-type thermoelectric element 3N) disposed between the substrates 2, a connection electrode 4C (electrodes 4) connecting the thermoelectric elements 3, a heating thermoelectric element 3H, the posts 110 and 111, and end electrode 4T connecting the posts 110 and 111 to the thermoelectric element 3.

The upper substrate 21 and the lower substrate 22 are formed of an electrically insulating material and have a plate shape. The upper substrate 21 is disposed above the lower substrate 22 so as to be opposite to the lower substrate, and is disposed at an interval. The upper substrate 21 and the lower substrate 22 are formed of ceramic, for example.

As shown in FIG. 12, a plurality of the thermoelectric elements 3 are disposed between the upper substrate 21 and the lower substrate 22 in a grid pattern at intervals in a plane direction orthogonal to the thickness direction of the upper substrate 21 and the lower substrate 22. That is, the thermoelectric element 3 is disposed so as to be opposite to the upper surface of the lower substrate 22 and the lower surface of the upper substrate 21 via the connection electrode 4C to be described later. The thermoelectric element 3 includes the p-type thermoelectric element 3P and the n-type thermoelectric element 3N, depending on polarities of a semiconductor included in the thermoelectric element 3. In the present embodiment, the p-type thermoelectric element 3P and the n-type thermoelectric elements 3N are arranged so as to alternate in cross-section.

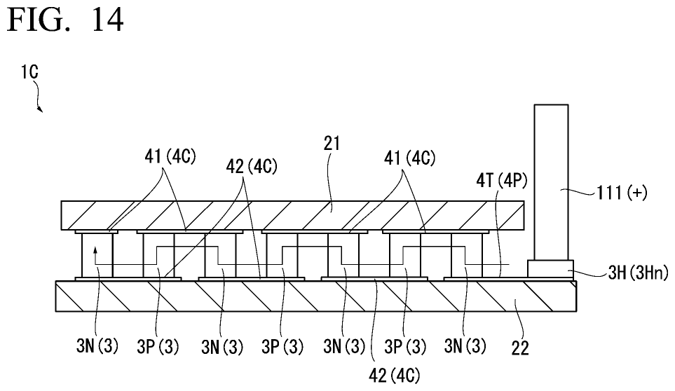

The connection electrode 4C includes an upper electrode 41 and a lower electrode 42. As shown in FIG. 13 or FIG. 14, the upper electrode 41 are provided on an upper end surfaces of the p-type thermoelectric element 3P and the n-type thermoelectric element 3N, and the lower electrodes 42 are provided on the lower end surfaces of the p-type thermoelectric element 3P and the n-type thermoelectric element 3N. Both the upper electrodes 41 and the lower electrodes 42 are wiring members formed of metal foil or the like on the substrate 2. The p-type thermoelectric element 3P and the n-type thermoelectric element 3N adjacent to the p-type thermoelectric element 3P are connected to each other by the lower electrode 42. The n-type thermoelectric element 3N and the p-type thermoelectric element 3P adjacent to the n-type thermoelectric element 3N are connected to each other by the upper electrode 41. Accordingly, the p-type thermoelectric elements 3P and the n-type thermoelectric elements 3N are alternately and sequentially connected to form a series circuit.

The end electrode 4T is disposed on the upper surface 22S of the lower substrate 22 and is connected to the thermoelectric element 3 positioned at the end of the series circuit. The end electrode 4T has a negative end electrode 4N and a positive end electrode 4P. As shown in FIG. 13, the negative end electrode 4N is connected to the p-type thermoelectric element 3P positioned on the most downstream side in a direction in which a current flows (current-flowing direction: an arrow in FIG. 13) among the thermoelectric elements 3 of the end of the series circuit. On the other hand, as shown in FIG. 14, the positive end electrode 4P is connected to the n-type thermoelectric element 3N positioned on the most upstream side in a current-flowing direction (arrow in FIG. 14) among the thermoelectric elements 3 of the end of the series circuit.

The heating thermoelectric element 3H having the same electrode type as that of the thermoelectric element 3 at the end of the series circuit is provided on the negative end electrode 4N and the positive end electrode 4P. Specifically, on the negative end electrode 4N, a p-type thermoelectric element (the heating p-type thermoelectric element 3Hp) having the same electrode type, that is, the same majority carrier as that of the p-type thermoelectric element 3P adjacent to the negative end electrode 4N is provided. Specifically, on the positive end electrode 4P, an n-type thermoelectric element (the heating n-type thermoelectric element 3Hn) having the same electrode type, that is, the same majority carrier as that of the n-type thermoelectric element 3N adjacent to the positive end electrode 4P is provided.

The posts 110 and 111 are erected on the respective heating thermoelectric elements 3H. The posts 110 and 111 are electrically connected to the thermoelectric elements 3 positioned at the ends of the series circuit described above via the end electrodes 4T. The post 110 functions as a negative electrode, and the post 111 functions as a positive electrode. The wires 112 for supplying a current from the outside are connected to the upper end surfaces of the posts 110 and 111. That is, the current is supplied from the wire 112 to the thermoelectric element 3 via the posts 110 and 111.

### <Effect>

Here, when a temperature controlled by the thermoelectric element 3 is lower than a dew point of a surrounding environmental atmosphere, dew condensation may occur in the thermoelectric module 1C. When the dew condensation occurs, a phenomenon called electrochemical migration is induced on the posts 110 and 111. The electrochemical migration is a phenomenon in which insulation between electrodes on an electric circuit becomes defective due to electrical, chemical, and heat factors, and electrode metal is eluted and reduced as ions to cause a short circuit. When such a phenomenon occurs, a stable operation of the thermoelectric module 1C may be hindered.

Therefore, in the present embodiment, the heating thermoelectric elements 3H is provided on each end electrode 4T. Specifically, the p-type thermoelectric element (the heating p-type thermoelectric element 3Hp) is provided on the negative end electrode 4N. The n-type thermoelectric element (the heating n-type thermoelectric element 3Hn) is provided on the positive end electrode 4P.

When the thermoelectric module 1C is in an energized state, heat is absorbed on the upper substrate 21 side where a current flows from the n-type thermoelectric element 3N to the p-type thermoelectric element 3P. On the other hand, heat is generated on the lower substrate 22 side where the current flows from the p-type thermoelectric element 3P to the n-type thermoelectric element 3N.

Here, the heating p-type thermoelectric element 3Hp on the negative end electrode 4N has the same electrode type as that of the p-type thermoelectric element 3P adjacent to the negative end electrode 4N. Therefore, the upper surface of the heating p-type thermoelectric element 3Hp generates heat. Also, the heating n-type thermoelectric element 3Hn on the positive end electrode 4P has the same electrode type, that is, the same majority carrier as that of the n-type thermoelectric element 3N adjacent to the positive end electrode 4P. Therefore, the upper surface of the heating n-type thermoelectric element 3Hn generates heat.

That is, the posts 110 and 111 respectively disposed on the heating thermoelectric elements 3H are heated, and for example, the temperature increases to a high temperature of 100° C. or higher. Therefore, in a case where water droplets adhere to the surfaces of the posts 110 and 111, the water droplets are heated and boiled, and then evaporated. As a result, it is possible to reduce the possibility that the electrochemical migration due to the retention of water droplets will occur.

In particular, in the above configuration, in a case where the thermoelectric element 3 disposed on the most downstream side in the current-flowing direction is the p-type, the heating thermoelectric element 3H adjacent to the thermoelectric element 3 is the p-type. Also, in a case where the thermoelectric element 3 disposed on the most upstream side in the current-flowing direction is the n-type, the heating thermoelectric element 3H adjacent to the thermoelectric element 3 is the n-type. As described above, when the thermoelectric element 3 having the same electrode type as that of the thermoelectric element 3 at the end of the series circuit formed with a plurality of thermoelectric elements 3 is provided on the end electrode 4T, it is possible to heat the posts 110 and 111 to easily suppress the adhering and retention of the water droplets.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims. For example, in the first to third embodiments, the case where the thermoelectric modules 1A to 1C are used as one element of the optical module 100 has been described. However, the thermoelectric modules 1A to 1C may be applied to other mechanical devices different from the optical module 100.

In the third embodiment, an example has been described in which the heating thermoelectric element 3H adjacent to the thermoelectric element 3 is the p-type when the thermoelectric element 3 disposed on the most downstream side in the current-flowing direction is the p-type, and the heating thermoelectric element 3H adjacent to the thermoelectric element 3 is the n-type when the thermoelectric element 3 disposed on the most upstream side in the current-flowing direction is the n-type. However, it is possible to adopt a configuration in which the heating thermoelectric element 3H adjacent to the thermoelectric element 3 is set to the n-type when the thermoelectric element 3 disposed on the most downstream side in the current-flowing direction is the n-type, and the heating thermoelectric element 3H adjacent to the thermoelectric element 3 is set to the p-type when the thermoelectric element 3 disposed on the most upstream side in the current-flowing direction is the p-type. When such a configuration is adopted, it is possible to heat the upper substrate 21 side, unlike the third embodiment.

What is claimed is:

1. A thermoelectric module comprising:
a lower substrate;
an upper substrate disposed above the lower substrate so as to be opposite to the lower substrate;
a plurality of p-type thermoelectric elements and n-type thermoelectric elements disposed between the lower substrate and the upper substrate;
first electrodes disposed on an upper surface of the lower substrate and a lower surface of the upper substrate, and sequentially connecting the p-type and n-type thermoelectric elements alternately to form a series circuit; and
a second electrode that is provided on the lower substrate and connects a thermoelectric element at an end of the series circuit to a post,
wherein the post includes
a post body formed of nickel, and
a nickel passivation film covering a side surface of the post body.

2. The thermoelectric module according to claim 1,
wherein the post further includes
a first plating part that is provided on a first surface of the post connected to the second electrode, and is formed of an alloy of gold and tin, and
a second plating part that is provided on a second surface of the post opposite to the first surface, and is formed of gold.

3. The thermoelectric module according to claim 2,
wherein the post further includes
an intermediate layer provided between the second plating part and the post and/or between the first plating part and the post.

4. The thermoelectric module according to claim 3,
wherein the intermediate layer is formed of at least one kind selected from the group consisting of gold, palladium, platinum, and rhodium.

5. A thermoelectric module comprising:
a lower substrate;
an upper substrate disposed above the lower substrate so as to be opposite to the lower substrate;
a plurality of p-type thermoelectric elements and n-type thermoelectric elements disposed between the lower substrate and the upper substrate;
electrodes disposed on an upper surface of the lower substrate and a lower surface of the upper substrate, and sequentially connecting the p-type thermoelectric elements and the n-type thermoelectric elements alternately so as to form a series circuit;
a pair of posts that are erected on the lower substrate at an interval and are electrically connected to both ends of the series circuit, respectively; and
a water-repellent coating layer laminated on a region between the pair of posts on the lower substrate.

6. The thermoelectric module according to claim 5, further comprising:
a hydrophilic coating layer laminated on a region of the pair of posts on the lower substrate, the region surrounding an outer periphery of each post.

7. The thermoelectric module according to claim 5, further comprising:
opposite surface water-repellent coating layers respectively formed on opposite surfaces of the pair of posts opposite to each other.

8. The thermoelectric module according to claim 7, further comprising:
opposite surface hydrophilic coating layers respectively formed on outer surfaces different from the opposite surfaces of the pair of posts.

9. The thermoelectric module according to claim 5,
wherein at least one of the upper substrate and the lower substrate has a sintered body formed in a plate shape and a permeable water-repellent material with which the sintered body is impregnated.

10. A thermoelectric module comprising:
a lower substrate;
an upper substrate disposed above the lower substrate so as to be opposite to the lower substrate;
a plurality of p-type thermoelectric elements and n-type thermoelectric elements disposed between the lower substrate and the upper substrate;
connection electrodes disposed on an upper surface of the lower substrate and a lower surface of the upper substrate, and sequentially connecting the p-type thermoelectric elements and the n-type thermoelectric elements alternately so as to form a series circuit;
an end electrode that is disposed on the upper surface of the lower substrate and is connected to the thermoelectric element at an end of the series circuit;
a heating thermoelectric element that is disposed on the end electrode and has the same majority carrier as the thermoelectric element at the end of the series circuit; and
a post erected on the heating thermoelectric element.

11. The thermoelectric module according to claim 10,
wherein the thermoelectric element at the end of the series circuit is a p-type thermoelectric element disposed on a most downstream side in a current-flowing direction, and
the heating thermoelectric element is a p-type thermoelectric element.

12. The thermoelectric module according to claim 11,
wherein the thermoelectric element at the end of the series circuit is an n-type thermoelectric element disposed on a most upstream side in the current-flowing direction, and
the heating thermoelectric element is an n-type thermoelectric element.

13. The thermoelectric module according to claim 10,
wherein the thermoelectric element at the end of the series circuit is an n-type thermoelectric element disposed on a most downstream side in a current-flowing direction, and
wherein the heating thermoelectric element is an n-type thermoelectric element.

14. The thermoelectric module according to claim 13,
wherein the thermoelectric element at the end of the series circuit is a p-type thermoelectric element disposed on a most upstream side in the current-flowing direction, and
wherein the heating thermoelectric element is an n-type thermoelectric element.

15. A method for manufacturing a thermoelectric module post, comprising:
a step of preparing a plate-shaped element body that is formed of nickel and has a pair of end surfaces which face directions away from each other in a thickness direction;
a step of forming a plated element body by plating one end surface of the element body in the thickness direction with gold and by plating the other end surface of the element body in the thickness direction with an alloy of gold and tin;
a step of forming a plurality of posts by dicing the plated element body from the thickness direction in a grid pattern; and
a step of forming a nickel passivation film on a side surface of the post by immersing the post in an oxidizing agent.

16. The method for manufacturing a thermoelectric module post according to claim 15,
wherein in the step of forming a plated element body, a step of forming an intermediate layer on one surface in the thickness direction of the element body is performed before being plated.

17. The method for manufacturing a thermoelectric module post according to claim 15,
wherein in the step of forming a plated element body, a step of forming intermediate layers on both surfaces in the thickness direction of the element body is performed before being plated.
